(19) United States
(12) Patent Application Publication
(10) Pub. No.: US 2025/0071983 A1
(43) Pub. Date: Feb. 27, 2025

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Kuo-Hsing Lee, Hsinchu County (TW); Sheng-Yuan Hsueh, Tainan City (TW); Yung-Chen Chiu, Taichung City (TW); Chih-Kai Kang, Tainan City (TW); Wen-Kai Lin, Yilan County (TW)

(73) Assignee: UNITED MICROELECTRONICS CORP., Hsin-Chu City (TW)

(21) Appl. No.: 18/372,130

(22) Filed: Sep. 24, 2023

(30) Foreign Application Priority Data
Aug. 23, 2023 (TW) 112131654

(51) Int. Cl. H10B 20/25

(52) U.S. Cl. CPC H10B 20/25

(57) ABSTRACT

A method for fabricating a semiconductor device includes the steps of first providing a substrate having a transistor region and an one time programmable (OTP) capacitor region, forming a first fin-shaped structure on the transistor region and a second fin-shaped structure on the OTP capacitor region, and then performing an oxidation process to form a gate oxide layer on the first fin-shaped structure and the second fin-shaped structure. Preferably, the first fin-shaped structure and the second fin-shaped structure have different shapes under a cross-section perspective.

### BACKGROUND OF THE INVENTION

### 1. Field of the Invention

The invention relates to a method for fabricating semiconductor device, and more particularly to a method for fabricating an one-time programmable (OTP) device.

### 2. Description of the Prior Art

Semiconductor memory devices including non-volatile memory devices have been widely used in various electronic devices such as cellular phones, digital cameras, personal digital assistants (PDAs), and other applications. Typically, non-volatile memory devices include multi-time programmable (MTP) memory devices and one-time programmable (OTP) memory devices. In contrast to rewritable memories, OTP memory devices have the advantage of low fabrication cost and easy storage. However, OTP memory devices could only perform a single data recording action such that when certain memory cells of a destined storage block were stored with a writing program, those memory cells could not be written again.

Since current OTP memory devices still have the disadvantage of weak reading current and longer stress time under program mode, how to improve the current architecture for OTP memory devices has become an important task in this field.

### SUMMARY OF THE INVENTION

According to an embodiment of the present invention, a method for fabricating a semiconductor device includes the steps of first providing a substrate having a transistor region and an one time programmable (OTP) capacitor region, forming a first fin-shaped structure on the transistor region and a second fin-shaped structure on the OTP capacitor region, and then performing an oxidation process to form a gate oxide layer on the first fin-shaped structure and the second fin-shaped structure. Preferably, the first fin-shaped structure and the second fin-shaped structure have different shapes under a cross-section perspective.

According to another aspect of the present invention, a semiconductor device includes a substrate having a transistor region and an one time programmable (OTP) capacitor region, a first fin-shaped structure on the transistor region and a second fin-shaped structure on the OTP capacitor region, and a first gate electrode on the first fin-shaped structure and a second gate electrode on the second fin-shaped structure. Preferably, the first fin-shaped structure and the second fin-shaped structure have different shapes.

According to yet another aspect of the present invention, a semiconductor device includes a substrate having a transistor region and an anti-fuse capacitor region, a first fin-shaped structure on the transistor region and a second fin-shaped structure on the anti-fuse capacitor region, and a first gate electrode on the first fin-shaped structure and a second gate electrode on the second fin-shaped structure. Preferably, the first fin-shaped structure and the second fin-shaped structure have different shapes.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-9 illustrate a method for fabricating a semiconductor device according to an embodiment of the present invention.

### DETAILED DESCRIPTION

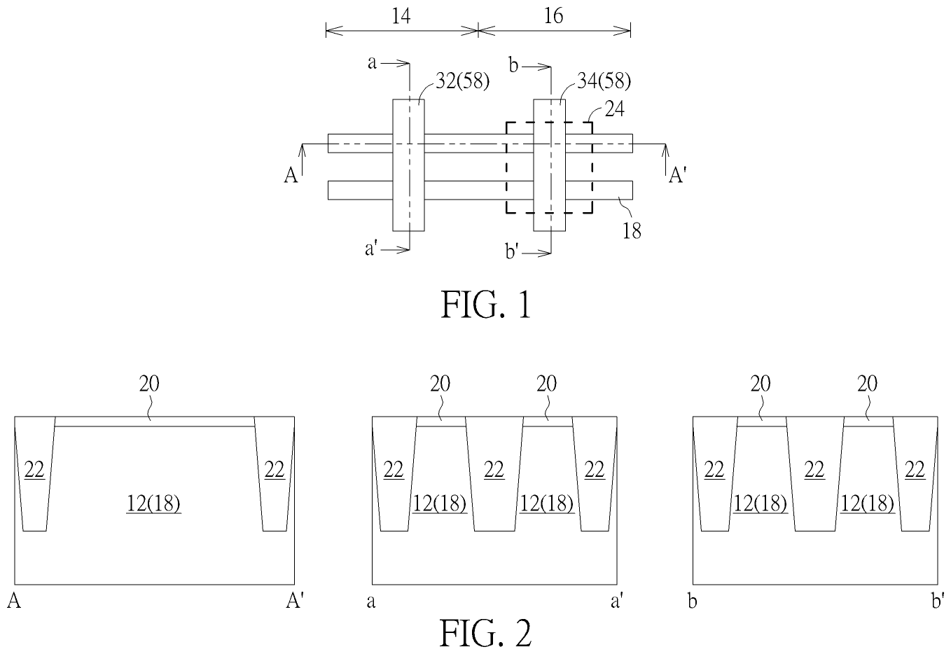

Referring to FIGS. 1-9, FIGS. 1-9 illustrate a method for fabricating a semiconductor device according to an embodiment of the present invention, in which FIG. 1 illustrates a top view for fabricating a OTP device and FIGS. 2-9 according to an embodiment of the present invention and FIGS. 2-9 illustrate cross-section views for fabricating the OTP device along the sectional lines AA′, aa′, and bb′ of FIG. 1. As shown in FIGS. 1-2, a substrate 12 such as a silicon substrate or silicon-on-insulator (SOI) substrate is provided and a transistor region 14 and a OTP capacitor region 16 are defined on the substrate 12, in which the transistor region 14 is used for preparing a metal-oxide semiconductor (MOS) transistor in the later process while the OTP capacitor region 16 is used for fabricating an OTP capacitor. In this embodiment, the transistor and the OTP capacitor formed on these two regions 14, 16 together constitute a 1 transistor-1 capacitor (1T1C) architecture.

Next, a plurality of fin-shaped structures 18 are formed on the substrate 12 of the transistor region 14 and the OTP capacitor region 16. Preferably, the fin-shaped structures 18 could be obtained by a sidewall image transfer (SIT) process. For instance, a layout pattern is first input into a computer system and is modified through suitable calculation. The modified layout is then defined in a mask and further transferred to a layer of sacrificial layer on a substrate through a photolithographic and an etching process. In this way, several sacrificial layers distributed with a same spacing and of a same width are formed on a substrate. Each of the sacrificial layers may be stripe-shaped. Subsequently, a deposition process and an etching process are carried out such that spacers are formed on the sidewalls of the patterned sacrificial layers. In a next step, sacrificial layers can be removed completely by performing an etching process. Through the etching process, the pattern defined by the spacers can be transferred into the substrate underneath, and through additional fin cut processes, desirable pattern structures, such as stripe patterned fin-shaped structures could be obtained.

Alternatively, the fin-shaped structures 18 could also be obtained by first forming a patterned mask (not shown) on the substrate, 12, and through an etching process, the pattern of the patterned mask is transferred to the substrate 12 to form the fin-shaped structures 18. Moreover, the formation of the fin-shaped structures 18 could also be accomplished by first forming a patterned hard mask (not shown) on the substrate 12, and a semiconductor layer composed of silicon germanium is grown from the substrate 12 through exposed patterned hard mask via selective epitaxial growth process to form the fin-shaped structures 18. These approaches for forming the fin-shaped structures 18 are all within the scope of the present invention.

In this embodiment, at least a liner (not shown) and a hard mask 20 could be formed on the surface of the fin-shaped structures 18 during the patterning of the fin-shaped structures 18, in which the liner preferably includes silicon oxide (SiO₂) or silicon nitride (SiN) and the hard mask 20 includes silicon oxide (SiO₂), but not limited thereto.

Next, a photo-etching process could be conducted to remove part of the substrate 12 adjacent to the transistor region 14 and OTP capacitor region 16 for forming at least two trenches, a flowable chemical vapor deposition (FCVD) process is conducted to form an insulating layer made of silicon oxide and fill the trenches, and a planarizing process such as chemical mechanical polishing (CMP) process is conducted to remove part of the insulating layer so that the top surface of the remaining the insulating layer 32 is even with the top surface of the hard mask 20 to form a shallow trench isolation (STI) 22.

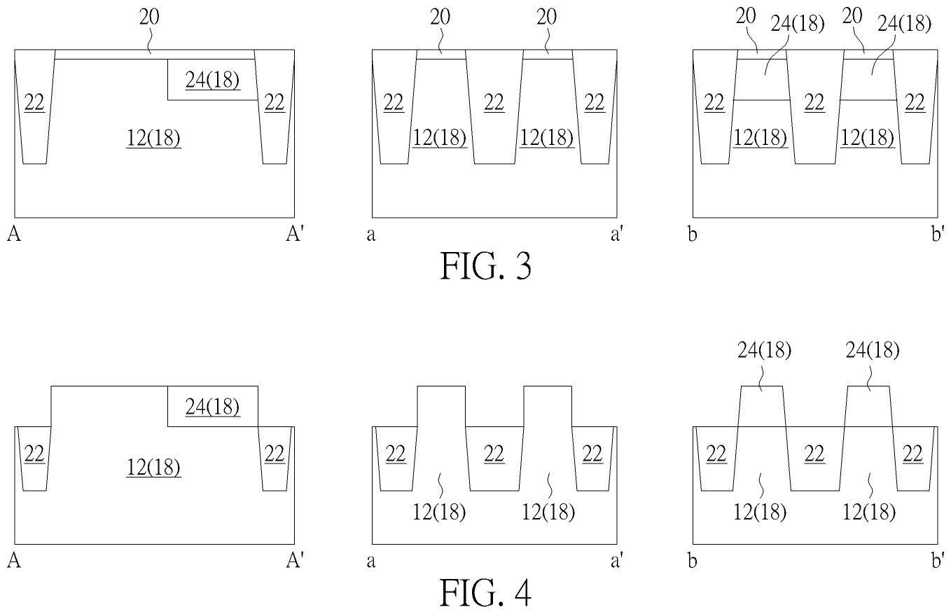

Next, as shown in FIG. 3, a patterned mask (not shown) such as a patterned resist is formed on the transistor region 14 to expose the substrate 12 surface of the OTP capacitor region 16, and an ion implantation process or a heavy doping process is conducted to implant dopants into the fin-shaped structures 18 on the OTP capacitor region 16 for forming a doped region 24. Accordingly, the overall doping concentration in the fin-shaped structures 18 of the transistor region 14 is now substantially less than the overall doping concentration in the fin-shaped structures 18 of the OTP capacitor region 16, in which the doped region 24 preferably serves as a bottom electrode for the OTP capacitor. In this embodiment, the implanted dopants preferably include arsenic (As), the energy of the ion implantation process is between 5-20 KeV, and the dosage of the dopants is between 1.0×10¹⁵ atoms/cm² to 1.0×10¹⁶ atoms/cm² and the concentration of dopants is approximately 1.0×10¹⁸ atoms/cm³ to 1.0×10²⁰ atoms/cm³.

Next, as shown in FIG. 4, an etching process is conducted to remove the hard mask 20 and part of the STI 22 adjacent to the fin-shaped structures 18 so that the top surface of the remaining STI 22 is slightly lower than the top surface of the fin-shaped structures 18. It should be noted that since the fin-shaped structures 18 on the OTP capacitor region 16 has higher doping concentration, the tip of the fin-shaped structures 18 on the transistor region 14 and the tip of the fin-shaped structures 18 on the OTP capacitor region 16 protruding above the surface of the STI 22 after part of the STI 22 is removed by the etching process would reveal different shapes if viewed from a cross-section perspective. Specifically, the fin-shaped structures 18 protruding above the STI 22 on the transistor region 14 preferably have rectangular cross-section as shown in the middle portion of FIG. 4 while the fin-shaped structures 18 protruding above the STI 22 on the OTP capacitor region 16 have trapezoid shape cross-section. In other words, the sidewalls of the fin-shaped structures 18 above the STI 22 on the transistor region 14 have vertical sidewalls while the sidewalls of the fin-shaped structures 18 above the STI 22 on the OTP capacitor region 16 have inclined sidewalls.

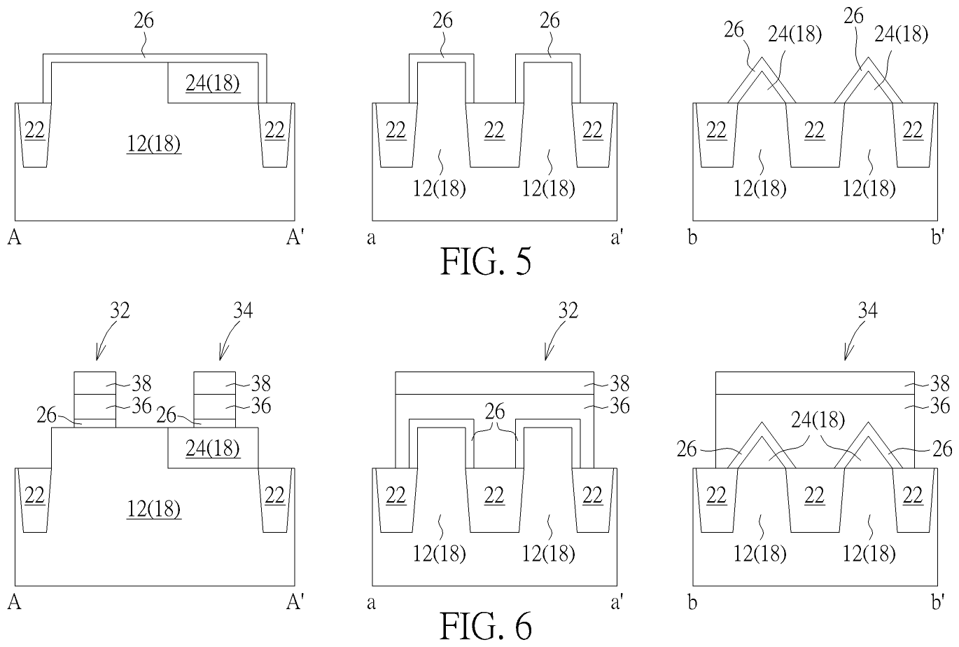

Next, as shown in FIG. 5, an oxide growth process such as a rapid thermal oxidation (RTO) process or in-situ steam generation (ISSG) process is conducted to form a gate oxide layer 26 made of silicon oxide on the fin-shaped structures 18 on both the transistor region 14 and the OTP capacitor region 16.

It should be further noted since the tip of the fin-shaped structures 18 protruding above the STI 22 on the transistor region 14 and OTP capacitor region 16 already have different shapes under cross-section perspective, the fin-shaped structures 18 on both regions 14, 16 at this stage also have different shapes after the gate oxide layer 26 is formed. Specifically, after the gate oxide layer 26 is formed on surface of the fin-shaped structures 18 on both the transistor region 14 and OTP capacitor region 16 through the oxide growth process, the fin-shaped structures 18 protruding above the STI 22 on the transistor region 14 still show rectangular shape under cross-section perspective whereas the fin-shaped structures 18 protruding above the STI 22 on the OTP capacitor region 16 is gradually changed from trapezoid to triangular shape cross-section. In other words, the gate oxide layer 26 on the transistor region 14 at this stage includes a planar top surface and two vertical sidewalls while the gate oxide layer 26 on the OTP capacitor region 16 only includes two inclined sidewalls.

Next, as shown in FIG. 6, gate electrodes 32, 34 are formed on the fin-shaped structures 18 on the transistor region 14 and OTP capacitor region 16 respectively, in which the gate electrode 32 formed on the transistor region 14 could be served as gate electrode for I/O device or LV device, the gate electrode 34 formed on the OTP capacitor region 16 could be used as top electrode for the OTP capacitor, and the formation of the gate electrodes 32, 34 could be accomplished by a gate first process, a high-k first approach from gate last process, or a high-k last approach from gate last process.

Since this embodiment pertains to a high-k last approach, a gate material layer 36 made of polysilicon and a selective hard mask 38 could be formed sequentially on the substrate 12, and a photo-etching process is then conducted by using a patterned resist (not shown) as mask to remove part of the hard mask 38, part of the gate material layer 36, and part of the gate oxide layer 26 through single or multiple etching processes. After stripping the patterned resist, gate electrodes 32, 34 each made of a patterned material layer 36 and patterned hard mask 38 is formed on the fin-shaped structures 18 of the transistor region 14 and OTP capacitor region 16.

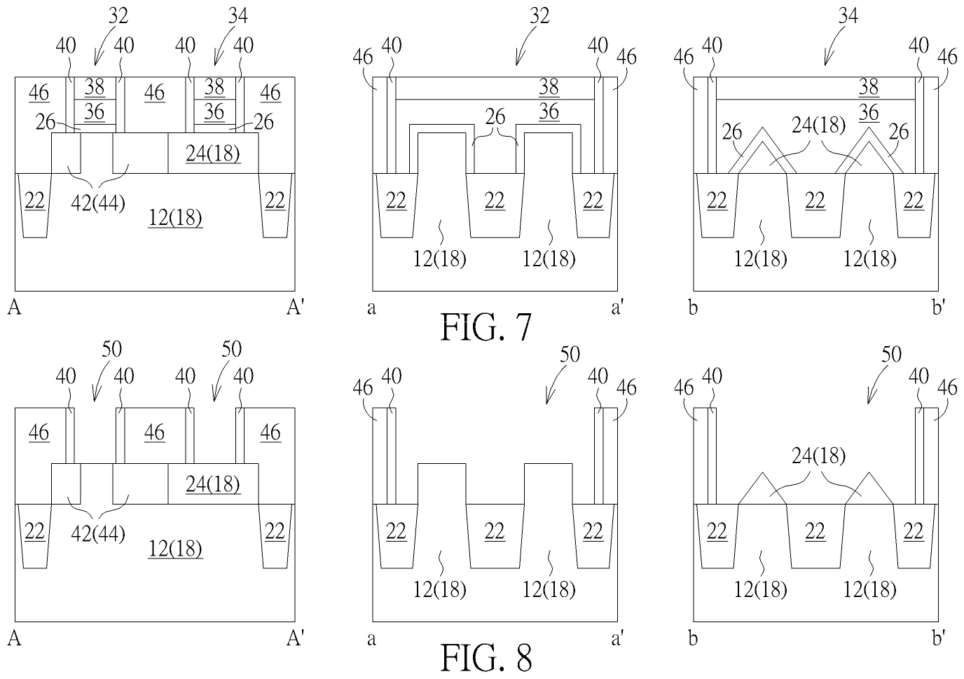

Next, as shown in FIG. 7, at least a spacer 40 is formed on the sidewalls of the each of the gate electrodes 32, 34, a source/drain region 42 and/or epitaxial layer 44 is formed in the fin-shaped structures 18 adjacent to two sides of the gate electrode 32, and selective silicide layers (not shown) could be formed on the surface of the source/drain region 42 and/or epitaxial layer 44. In this embodiment, the spacer 40 could be a single spacer or a composite spacer, such as a spacer including but not limited to for example an offset spacer and a main spacer. Preferably, the offset spacer and the main spacer could include same material or different material while both the offset spacer and the main spacer could be made of material including but not limited to for example SiO₂, SiN, SiON, SiCN, or combination thereof.

The source/drain region 42 and the epitaxial layer 44 could include different dopants or different materials depending on the type of device being fabricated. For instance, the source/drain region 42 could include n-type dopants or p-type dopants and the epitaxial layers 44 could include silicon germanium (SiGe), silicon carbide (SiC), or silicon phosphide (SiP). It should be noted that since a capacitor is fabricated on the OTP capacitor region 16, the source/drain region 42 is only formed in the fin-shaped structure 18 adjacent to two sides of the gate electrode 32 on the transistor region 14 while no source/drain region and/or epitaxial layer is formed in the fin-shaped structures 18 adjacent to two sides of the gate electrode 34 on the OTP capacitor region 16.

Next, an interlayer dielectric (ILD) layer 46 is formed on the gate electrodes 32, 34 and a planarizing process such as CMP is conducted to remove part of the ILD layer 46 for exposing the hard masks 38 so that the top surface of the hard masks 38 are even with the top surface of the ILD layer 46.

Next, as shown in FIG. 8, a replacement metal gate (RMG) process is conducted to transform the gate electrodes 32, 34 on the transistor region 14 and OTP capacitor region 16 into metal gates. For instance, the RMG process could be accomplished by first performing a selective dry etching or wet etching process using etchants including but not limited to for example ammonium hydroxide (NH₄OH) or tetramethylammonium hydroxide (TMAH) to remove the hard masks 38, the gate material layer 36, and even the gate oxide layer 26 for forming recesses 50 in the ILD layer 46.

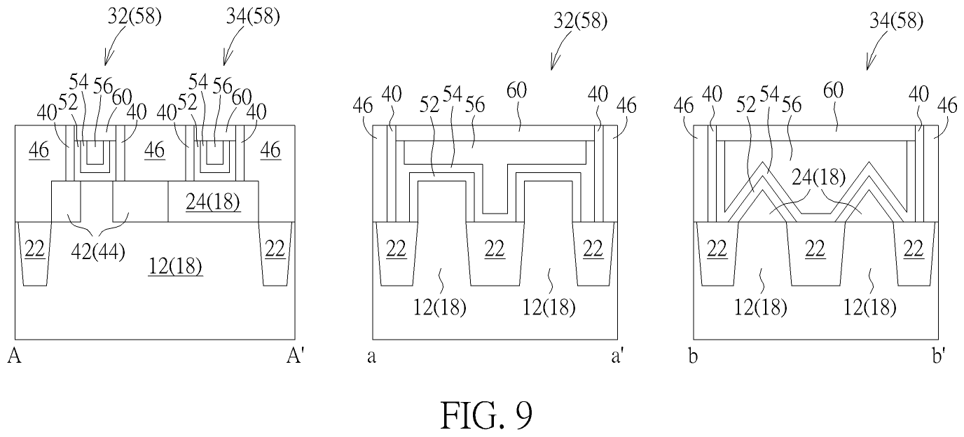

Next, as shown in FIG. 9, a selective interfacial layer (not shown) or gate dielectric layer, a high-k dielectric layer 52, a work function metal layer 54, and a low resistance metal layer 56 are formed in the recesses 50, and a planarizing process such as CMP is conducted to remove part of low resistance metal layer 56, part of work function metal layer 54, and part of high-k dielectric layer 52 to form metal gates 58. In this embodiment, the gate structures or metal gates 58 fabricated through high-k last process of a gate last process preferably includes an interfacial layer or gate oxide layer (not shown), a U-shaped high-k dielectric layer 52, a U-shaped work function metal layer 54, and a low resistance metal layer 56.

In this embodiment, the high-k dielectric layer 52 is preferably selected from dielectric materials having dielectric constant (k value) larger than 4. For instance, the high-k dielectric layer 50 may be selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalate (SrBi₂Ta₂O₉, SBT), lead zirconate titanate (PbZrₓTi₁₋ₓO₃, PZT), barium strontium titanate (BaₓSr₁₋ₓTiO₃, BST) or a combination thereof.

In this embodiment, the work function metal layer 54 is formed for tuning the work function of the metal gate in accordance with the conductivity of the device. For an NMOS transistor, the work function metal layer 54 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 54 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 54 and the low resistance metal layer 56, in which the material of the barrier layer may include titanium (Ti), titanium nitride (TiN), tantalum (Ta) or tantalum nitride (TaN). Furthermore, the material of the low-resistance metal layer 56 may include copper (Cu), aluminum (Al), titanium aluminum (TiAl), cobalt tungsten phosphide (CoWP) or any combination thereof.

Next, part of the high-k dielectric layer 52, part of the work function metal layer 54, and part of the low resistance metal layer 56 are removed to form recesses (not shown), and a hard mask 60 is formed into each of the recesses so that the top surfaces of the hard masks 60 and the ILD layer 46 are coplanar. Preferably the hard masks 60 could include SiO₂, SiN, SiON, SiCN, or combination thereof.

Next, another dielectric layer (not shown) could be formed on the ILD layer 46 and a photo-etching process is conducted by using a patterned mask (not shown) as mask to remove part of the ILD layer 46 and dielectric layer adjacent to and/or directly on top of the gate electrodes 32, 34 for forming contact holes (not shown) exposing the source/drain region 42 and gate electrodes 32, 34. Next, conductive materials including a barrier layer selected from the group consisting of titanium (Ti), titanium nitride (TiN), tantalum (Ta), and tantalum nitride (TaN) and a metal layer selected from the group consisting of tungsten (W), copper (Cu), aluminum (Al), titanium aluminide (TiAl), and cobalt tungsten phosphide (CoWP) are deposited into the contact holes, and a planarizing process such as CMP is conducted to remove part of aforementioned barrier layer and low resistance metal layer for forming contact plugs (not shown) electrically connecting the source/drain region 42 and the gate electrodes 32, 34. In this embodiment, the source/drain region 42 on the transistor region 14 is connected to a bit line (BL) through the contact plugs, the gate electrode 32 is connected to a word line (WL) through the contact plugs, and the gate electrode 34 is connected to a source line (SL) through the contact plugs. This completes the fabrication of a semiconductor device according to an embodiment of the present invention.

Referring again to FIG. 9, FIG. 9 further illustrates a structural view of a OTP device according to an embodiment of the present invention. As shown in FIG. 9, the OTP device includes a MOS transistor disposed on the transistor region 14 and a OTP capacitor disposed on the OTP capacitor region 16, in which the MOS transistor includes a gate electrode 32 disposed on the fin-shaped structure 18 while the OTP capacitor includes fin-shaped structure 18 disposed on the substrate 12, at least an insulating layer such as a gate oxide layer (not shown) and/or a high-k dielectric layer 52 disposed on the fin-shaped structure 18, and a metal such as a work function metal layer 54 and/or low resistance metal layer 56 disposed on the high-k dielectric layer 52. Preferably, the fin-shaped structure 18 including a heavy doped region 24 is serving as a bottom electrode for the OTP capacitor, a dielectric material including the gate oxide layer and/or high-k dielectric layer 52 is serving as a capacitor dielectric layer for the OTP capacitor, and the work function metal layer 54 and low resistance metal layer 56 are serving as a top electrode for the OTP capacitor.

Preferably, the fin-shaped structure 18 directly under the gate electrode 32 on the transistor region 14 and the fin-shaped structure 18 under the gate electrode 34 on the OTP capacitor region 16 have different shapes under a cross-section perspective. Specifically, the fin-shaped structure 18 on the transistor region 14 includes a rectangular shape such as a rectangle or square if viewed from the sectional line aa′ direction while the fin-shaped structure 18 on the OTP capacitor region 16 includes a triangle if viewed from the sectional line bb′ direction. In this embodiment, each of the gate electrodes 32, 34 includes a high-k dielectric layer 52 disposed on the fin-shaped structure 18, a work function metal layer 54 disposed on the high-k dielectric layer 52, and a low resistance metal layer 56 disposed on the work function metal layer 54, in which the high-k dielectric layer 52 directly contacting the fin-shaped structure 18 and the fin-shaped structure 18 underneath preferably have same profile. For instance, the high-k dielectric layer 52 in the gate electrode 32 on the transistor region 14 includes a planar surface and two vertical sidewalls on the rectangular fin-shaped structure 18 while the high-k dielectric layer 52 in the gate electrode 34 on the OTP capacitor region 16 includes two inclined sidewalls disposed on the triangular fin-shaped structure 18.

It should also be noted that even though the high-k dielectric layer 52 contacts the fin-shaped structure 18 underneath in this embodiment, according to other embodiment of the present invention, it would also be desirable to form an additional interfacial layer or gate oxide layer made of silicon oxide between the fin-shaped structure 18 and the high-k dielectric layer 52 on both transistor region 14 and OTP capacitor region 16. In this instance, the interfacial layer directly contacting the fin-shaped structure 18 and the high-k dielectric layer 52 above would all include same profile such as all having a planar top surface with two vertical sidewalls on the transistor region 14 or all having two inclined sidewalls on the OTP capacitor region 16, which are all within the scope of the invention.

According to yet another embodiment of the present invention, instead of using the capacitor on the OTP capacitor region 16 to function as an OTP capacitor, it would also be desirable to follow the aforementioned processes conducted in FIGS. 1-9 for fabricating the capacitor on the region 16 and using such capacitor as an anti-fuse capacitor. In such instance, transistor on the transistor region 14 could be omitted and the region 16 would then be defined as an anti-fuse capacitor region instead of an OTP capacitor region, which is also within the scope of the present invention.

Overall, the present invention discloses an approach of fabricating an OTP capacitor having a 1 transistor-1 capacitor (1T1C) architecture, which first forms at least a fin-shaped structure on a substrate on the transistor region and OTP capacitor region, forms a heavy doped region 24 in the fin-shaped structure on the OTP capacitor region, and then conducts an oxidation process to form a gate oxide layer on the fin-shaped structure on both transistor region and OTP capacitor region, in which the fin-shaped structure on the transistor region and the OTP capacitor region due to different doping concentration preferably form different shapes during the oxidation process. According to a preferred embodiment of the present invention, the fin-shaped structure on the transistor region having lower doping concentration preferably include a rectangular such as a rectangle or square profile under a cross-section perspective while the fin-shaped structure on the OTP capacitor region having higher doping concentration preferably include a triangular cross-section. By using the aforementioned process to transform the tip of the fin-shaped structure on the OTP capacitor into a tapered profile, it would be desirable to improve gathering of electric field on the OTP capacitor region and lower the breakdown voltage of the OTP capacitor so that programming and performance of the device could be boosted substantially.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for fabricating a semiconductor device, comprising:
providing a substrate having a transistor region and an one time programmable (OTP) capacitor region;
forming a first fin-shaped structure on the transistor region and a second fin-shaped structure on the OTP capacitor region; and
performing an oxidation process to form a gate oxide layer on the first fin-shaped structure and the second fin-shaped structure, wherein the first fin-shaped structure and the second fin-shaped structure comprise different shapes.

2. The method of claim 1, further comprising:
performing a heavy doping process to form a doped region in the second fin-shaped structure;
forming a first gate electrode on the first fin-shaped structure and a second gate electrode on the second fin-shaped structure;
forming a source/drain region adjacent to two sides of the first gate electrode;
forming an interlayer dielectric (ILD) layer around the first gate electrode and the second gate electrode; and
performing a replacement metal gate (RMG) process to transform the first gate electrode and the second gate electrode into a first metal gate and a second metal gate.

3. The method of claim 2, wherein a concentration of dopants in the first fin-shaped structure is less than a concentration of dopants in the second fin-shaped structure.

4. The method of claim 1, wherein the first fin-shaped structure comprises a rectangle in a cross-section perspective.

5. The method of claim 1, wherein the second fin-shaped structure comprises a triangle in a cross-section perspective.

6. A semiconductor device, comprising:
a substrate having a transistor region and an one time programmable (OTP) capacitor region;
a first fin-shaped structure on the transistor region and a second fin-shaped structure on the OTP capacitor region, wherein the first fin-shaped structure and the second fin-shaped structure comprise different shapes; and
a first gate electrode on the first fin-shaped structure and a second gate electrode on the second fin-shaped structure.

7. The semiconductor device of claim 6, wherein a concentration of dopants in the first fin-shaped structure is less than a concentration of dopants in the second fin-shaped structure.

8. The semiconductor device of claim 6, wherein the first fin-shaped structure comprises a rectangle in a cross-section perspective.

9. The semiconductor device of claim 6, wherein the second fin-shaped structure comprises a triangle in a cross-section perspective.

10. The semiconductor device of claim 6, wherein the first gate electrode comprises a metal gate.

11. The semiconductor device of claim 6, wherein the first gate electrode comprise:
a high-k dielectric layer on the first fin-shaped structure;
a work function metal layer on the high-k dielectric layer; and
a low resistance metal layer on the work function metal layer.

12. A semiconductor device, comprising:
a substrate having a transistor region and an anti-fuse capacitor region;
a first fin-shaped structure on the transistor region and a second fin-shaped structure on the anti-fuse capacitor region, wherein the first fin-shaped structure and the second fin-shaped structure comprise different shapes; and
a first gate electrode on the first fin-shaped structure and a second gate electrode on the second fin-shaped structure.
